(19) United States
(12) Patent Application Publication
(10) Pub. No.: US 2025/0047060 A1
(43) Pub. Date: Feb. 6, 2025

(54) TO CAN TYPE SEMICONDUCTOR LASER DIODE PACKAGE MODULE

(71) Applicant: QSI CO., LTD., Cheonan-si (KR)

(72) Inventors: Jung Hyun PARK, Cheonan-si (KR); An Sik CHOI, Cheonan-si (KR)

(73) Assignee: QSI CO., LTD., Cheonan-si (KR)

(21) Appl. No.: 18/453,680

(22) Filed: Aug. 22, 2023

(30) Foreign Application Priority Data
Jul. 31, 2023 (KR) 10-2023-0099361

(51) Int. Cl. H01S 5/024; H01S 5/00; H01S 5/02212; H01S 5/0231

(52) U.S. Cl. CPC H01S 5/02415; H01S 5/0014; H01S 5/02212; H01S 5/0231

(57) ABSTRACT

A semiconductor laser diode, more particularly to a TO Can package module with a structure with no beam path change, combined with a temperature control function for stability of the beam properties emitted by the laser diode are described. The TO CAN type laser diode package module includes a stem heat block including a stem base forming a bottom and a heat block protruding from the stem base; a thermo-electric cooler (TEC) with a temperature control function, and the TEC is fixed to the surface including the vertical component of the heat block; a sub-mount fixed on the thermo-electric cooler; a laser diode chip and a thermistor; a plurality of lead pins arranged at predetermined intervals on the stem base; a monitoring photodiode (MPD) to monitor the beam emitted from the laser diode chip; and wires connecting each of the devices to the lead pins.

### CROSS-REFERENCE TO RELATED APPLICATIONS

This application claims the priority of Korean Patent Application No. 10-2023-0099361 filed on Jul. 31, 2023, in the Korean Intellectual Property Office, the disclosure of which is incorporated herein by reference.

### FIELD OF THE INVENTION

The present invention relates to a semiconductor laser diode, more particularly to a TO Can package module with a structure with no beam path change, combined with a temperature control function for stability of the beam properties emitted by the laser diode.

### BACKGROUND OF THE INVENTION

Conventionally, butterfly-type packages with an embedded thermo-electric cooler (TEC) for temperature control, or a TO CAN package with a TEC and a 45° reflection mirror, has been applied to manufacturing of optical modules to maintain the optical output properties of semiconductor laser diodes constantly, i.e., temperature-dependent power output and temperature-dependent wavelength variation, in technical applications requiring high reliability and high performance. However, butterfly-type packages provide disadvantages in manufacturing of optical modules that require price competitiveness because of the high cost of subsidiary materials and parts for packaging and low manufacturing. In addition, TO CAN-type package products equipped with TEC and 45° reflective mirrors also use 45° reflective mirrors, which leads to an increase in the number of assembly processes and an increase in package assembly costs.

To address the high unit cost of these butterfly packages, Korean Patent No. 10-1980288 proposes a configuration in which the TO CAN package is equipped with a TEC for temperature control. However, the structure described in the above disclosure requires a 45° reflective mirror part to change a path of a beam, and it is unavoidable to increase the assembly labor and increase the package assembly cost by using a 45° reflective mirror.

### SUMMARY OF THE INVENTION

The object of the present invention is to provide a TO-CAN type semiconductor laser diode package module that can maintain optical output properties of a semiconductor laser diode, such as the optical output with respect to temperature and the width of variation of the wavelength with respect to temperature, while reducing the manufacturing cost. Accordingly, the purpose of the present invention is to provide a TO CAN type semiconductor laser diode package module including a TEC and without changing the beam path.

In accordance with the objectives mentioned above, the present invention provides a TO CAN package module in which a LD chip and a sub-mount are placed on a stem for laser diode, while increasing the number of lead pins arranged in the stem base by expanding the diameter of the stem base, and the TEC, LD chip, thermistor, and photodiode are independently connected to a plurality of electrode lead pins located in the stem to achieve temperature-controllable high performance properties.

The present invention provides a TO CAN type laser diode package module including:
a stem heat block including a stem base forming a bottom and a heat block protruding from the stem base;
a thermo-electric cooler (TEC) with a temperature control function, wherein the heat block has a surface including a vertical component, and the TEC is fixed to the surface including the vertical component of the heat block;
a sub-mount fixed on the thermo-electric cooler;
a laser diode chip and a thermistor fixed on the sub-mount;
a plurality of lead pins arranged at predetermined intervals on the stem base;
a monitoring photodiode (MPD) disposed on the stem base to monitor the beam emitted from the laser diode chip; and
wires connecting each of the devices to the lead pins,
wherein the TO CAN type laser diode package module is characterized in that emitted beams from the laser diode chip travel in the desired direction without changing its path.

Also, the present invention provides a TO CAN type laser diode package module including:
a stem base forming a bottom;
a plurality of lead pins arranged at predetermined intervals on the stem base;
a thermo-electric cooler (TEC) with a temperature control function, supported and fixed by two of the lead pins;
a sub-mount fixed on the thermos-electric cooler;
a laser diode chip and a thermistor fixed on the sub-mount;
a monitoring photodiode (MPD) placed on the stem base to monitor the beam emitted from the laser diode chip; and
wires connecting each of the devices to the lead pins,
wherein the TO CAN type laser diode package module is characterized in that emitted beams from the laser diode chip travel in the desired direction without changing its path.

Also, the present invention provides a sub-mount module for a TO CAN type laser diode package including
a sub-mount;
a laser diode chip on the sub-mount;
a thermistor that monitors the temperature of the laser diode chip on the sub-mount; and
a monitoring photodiode (MPD) that monitors the beam emitted from the laser diode chip on the sub-mount.

The present invention provides a TO CAN type laser diode package module including:
a stem heat block including a stem base forming a bottom and a heat block protruding from the stem base;
a thermo-electric cooler (TEC) with a temperature control function, wherein the heat block has a surface including a vertical component, and the TEC is fixed to the surface including the vertical component of the heat block;
the above said sub-mount module for the TO CAN type laser diode package fixed to the thermo-electric cooler (TEC);
a plurality of lead pins arranged at predetermined intervals on the stem base; and
wires connecting each of the devices to the lead pins,
wherein the TO CAN type laser diode package module is characterized in that emitted beams from the laser diode chip travel in the desired direction without changing its path.

Also, the present invention provides a TO CAN type laser diode package module Including:
a stem base forming a bottom;
a plurality of lead pins arranged at predetermined intervals on the stem base;
a thermo-electric cooler (TEC) with a temperature control function, supported and fixed by two of the lead pins;
the above said sub-mount module for the TO CAN type laser diode package fixed to the thermoelectric cooler (TEC); and
wires connecting each of the devices to the lead pins,
wherein the TO CAN type laser diode package module is characterized in that emitted beams from the laser diode chip travel in the desired direction without changing its path.

In the above, it provides a TO CAN type laser diode package module characterized in that some of the lead pins are arranged in two rows along the diameter of the stem base, with a diameter between them (in parallel to the X-axis direction), and others are arranged along the Y-axis direction from the center of the stem base.

In the above, it provides a TO CAN type laser diode package module which characterizes in that:
the lead pins include eight,
wherein pin 1 is an NC pin for signal input or inspection, pin 2 is connected to a cathode of the laser diode chip, pin 3 arranged behind the heat block, is connected to the monitoring photodiode anode, pin 4 is connected to an anode the laser diode chip, pin 5 is the signal input pin, pin 6 is connected to the (−) terminal of a thermos-electric cooler, pins 7 and 9 are connected to a thermistor, pin 8 is connected to an MPD anode, and pin 10 is connected to the (+) terminal of a thermos-electric cooler.

In the above, it provides a TO CAN type laser diode package module characterized in that pins 1, 2, 4, 5, 6, 7, 9, and 10 are arranged in two rows along the transverse diameter (X-axis direction) of the stem base, pin 3 is placed at a position shifted from the center of the stem base in the +Y axis direction, and pin 8 is placed at a position shifted from the center of the stem base in the −Y direction.

In the above, it provides a TO CAN type laser diode package module characterized in that a heat block is disposed in an eccentric part biased in the +Y direction from the center of a stem base.

In the above, it provides a TO CAN type laser diode package module characterized by the presence of an insulator between the thermos-electric cooler and the lead pin supporting the thermos-electric cooler.

According to the present invention, laser diode chips, TEC, and thermistors are formed in the TO CAN system, it provides a laser diode package module capable of temperature control of a semiconductor laser diode chip without applying 45° reflective mirror parts to change beam path direction. As a result, the semiconductor laser diode package module of the present invention may be cost competitive and miniaturized compared to the conventional butterfly packages.

In other words, according to the present invention, the laser diode chip and the thermistor detecting temperature variation are bonded on the same sub-mount and fixed to the vertical surface of the heat block, so that the beam emitted from the laser diode chip can be emitted and traveling straight to the top of a TO CAN without a mirror, the present invention eliminating the need for a mirror and a process for assembling the mirror, thereby simplifying components and reducing the number of process.

Furthermore, the TO CAN semiconductor laser diode package module of the present invention, in which a mirror is omitted, is more advantageous in terms of reliability and durability because the beam direction caused by the mirror can be sensitively changed.

Furthermore, according to the present invention, a thermo-electric cooler (TEC) is placed between the sub-mount and the heat block to stabilize the optical output properties of the semiconductor laser diode, such as the output (optical power, beam profile etc.) and the width of variation of the wavelength according to temperature, with high reliability.

Furthermore, according to the present invention, as many lead pins as necessary can be arranged at appropriate intervals by expanding the area of the stem base on which the heat block is arranged, thereby enabling arrangement of sufficient devices that can control the optical properties of the laser beam, such as a thermo-electric cooler and a thermistor, and there is sufficient space in terms of reducing process difficulty and preventing short circuits in connecting each of the lead pins to the devices on the heat block with gold wires.

Furthermore, according to a modified embodiment of the present invention, a monitoring photo diode (MPD) which receives and monitors beams emitted from the laser diode chip is placed on a sub-mount with a laser diode chip and a thermistor arranged, rather than on the bottom surface of the stem base, thereby the process of assembling the MPD can be omitted, further simplifying the number of processes, freeing up the space occupied by the lead pins and gold wires, and increasing the reliability of the MPD's beam monitoring function.

Furthermore, according to a modified embodiment of the present invention, the heat block is omitted and the TEC is supported and fixed on the lead pins, thereby simplifying the number of processes and providing a more compact TO CAN package module at a lower cost.

### BRIEF DESCRIPTION OF THE DRAWINGS

FIG. 1 is a cross-sectional view, showing a TO CAN package configuration equipped with a 45° reflective mirror (342), referring to prior art South Korean Patent No. 10-1980288.

FIG. 2a is a cross-sectional view illustrating a temperature controllable TO CAN package configuration including a laser diode chip, a TEC, a thermistor, and a photodiode that do not require a 45° reflective mirror to change the direction of beam emission according to the present invention,

FIG. 2b is a top view showing the location of each lead pin.

FIG. 2c shows a case where the thickness of the heat block is made thinner.

FIG. 3 is a cross-sectional view illustrating a TO CAN package configuration with another photodiode-embedded sub-mount module in accordance with the present invention.

FIGS. 4 to 7 are modified embodiments of the present invention, showing cross-sectional configurations of TO CAN package modules with a TEC including a laser diode chip, bonded to the lead pins without a heat block.

### DETAILED DESCRIPTION

Hereinafter, preferred embodiments of the present invention will be described in detail with reference to the accompanying drawings.

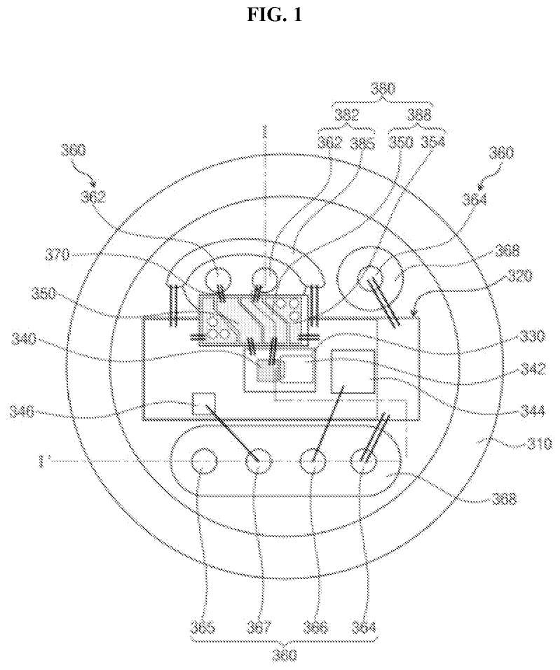

The prior art in FIG. 1 (TO-CAN package with TEC for temperature control, Korean Patent No. 10-1980288) shows a configuration with a sub-mount, a laser diode, and a thermistor on a thermo-electric cooler (TEC), which is attached to the bottom inside the TO stem, and a 45° reflective mirror to reroute the beam, so that the laser beam is emitted in vertical direction. As mentioned above, this configuration requires a separate optical system to be configured inside the TO stem to change the direction of the laser beam path, which increases the number of assembly processes and package assembly cost due to the application of 45° reflective mirror, making the fabrication process cumbersome and expensive, and the package module unable to be compact.

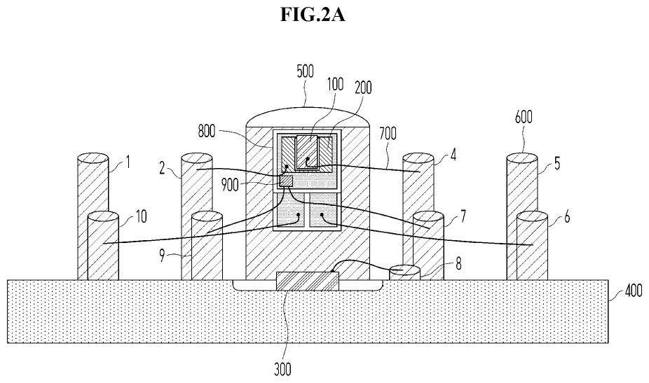

Improving on these points, the present invention omits optical systems for changing the direction of the beam path, such as 45° reflective mirror or a prism, as shown in FIG. 2, to provide a TO-CAN type package without changing the beam path of the laser beam, and provides a TO-CAN type laser diode package module including a TEC to keep the optical output and wavelength variation width according to temperature constant.

In a typical laser diode TO CAN package module, the sub-mount body, which holds the light emitting device LD and the light receiving device PD, is fixed on a heat block. The heat block also serves as a base for supporting the laser diode, and the three lead pins extending through the underside of the heat block to the back of the heat block provide electrical contacts for power supply and signal input. Conventional TO CAN laser diode package module can irradiate laser beams in the vertical direction of the stem base without change the beam path, but it is difficult to embed a thermo-electric cooler and a thermistor in a TO-CAN package module due to a limit of the size of the heat block and the number of lead pins, making it impossible to maintain a constant temperature-dependent output and temperature-dependent wavelength variation in applications that require high reliability and high performance properties.

In the present invention, as shown in FIG. 2a, the diameter of the stem base (400) is expanded to increase the number of leads (600) that can be included, and after bonding thermo-electric cooler (800) with the laser diode chip (100) and the thermistor (900) on the heat block (500) (on a vertical or inclined surface with vertical components surface of the heat block), a plurality of electrode leads (600) disposed in the stem base and the devices are connected independently using the (gold) wire (700).

In other words, the lead indicated by 600 refers to eight pins (synonymous with lead pins), six pins placed in two rows around the periphery of the heat block (500), along and across the diameter of the stem base (400) (parallel to X-axis direction), and the remaining two pins placed at the front and rear of the heat block (arrangement in the Y-axis direction). The location of the pins are shown in a top view in FIG. 2b.

Pin 1 is placed as an NC pin (for signal input, or for inspection), pin 2 is connected to cathode of the laser diode, pin 3 arranged behind the heat block (500) (see FIG. 2b), is connected to the MPD (monitoring photodiode) anode, and pin 4 is connected to the laser diode anode, pin 5, labeled as lead (600), is for signal input, pin 6 is connected to the (−) terminal of the thermo-electric cooler, pins 7 and 9 are connected to the thermistor (900), pin 8 is connected to the MPD anode, and pin 10 is connected to the (+) terminal of the thermoelectric cooler by gold wires (700).

According to the TO CAN package layout shown in FIG. 2a, pins 1, 2, 4, 5, 6, 7, 9, and 10 are placed in two rows along the traverse diameter of the stem base (400) (in the X-axis direction), and a heat block (500) is placed on an eccentric portion slightly biased in the +Y direction from the center of the stem base, MPD (300) is placed at the eccentricity in the −Y direction, pin 3 is placed at the back of the heat block, partially overlapping the heat block, and pin 8 is disposed at a location further advanced in the −Y direction from the MPD location.

This layout allows for an increased number of pins due to the increased diameter of the stem base, which simplifies components, simplifies the process, and improves reliability by eliminating mirror components with tight machining and assembly tolerances.

A thermo-electric cooler (800) is bonded on the vertical surface of the heat block (500), and a sub-mount (200) fixing the laser diode chip (100) is precisely bonded on the thermo-electric cooler. A thermistor (900) is attached to the lower part of the bonding portion of the thermo-electric cooler (800) to monitor the temperature transmitted to the laser diode chip (100). Accordingly, the temperature is controlled by the thermo-electric cooler (800) to improve the optical properties.

A monitoring PD (300) is attached to the bottom, a surface of the TO stem base (400) to detect and control the optical output (optical power, beam profile etc.) of the laser diode. Each of the above devices in the TO CAN package is independently connected via gold wires (700) to a plurality of electrode lead (600) pins disposed on the stem base. For reference, in FIG. 2a, for convenience, a reference numeral 600 is assigned to one lead pin.

In addition, as a modified embodiment for the above embodiments, the width or thickness of the heat block (500) in FIG. 2b can be narrowed to make its cross-section a thin rectangle (see FIG. 2c). A thermo-electric cooler (800), including the thermistor (900) and the laser diode chip (100), are bonded to the vertical surface of the thin heat block (500), and the thin heat block (500) provides more space for placement of the lead pins. The connection between each device and each of the pins by the gold wires (700) is shown in FIG. 2a.

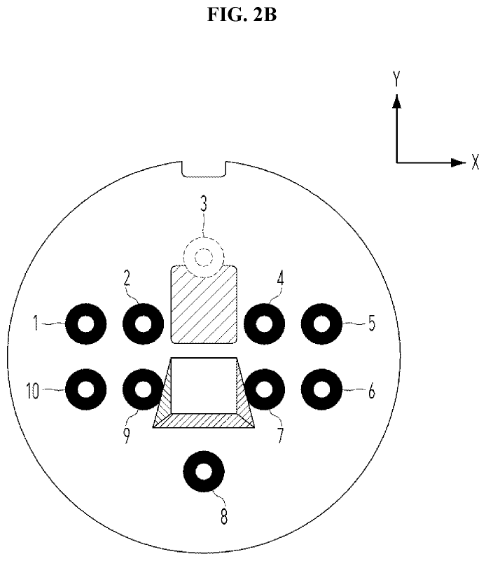

FIG. 3 is another embodiment of the present invention, and shows a more simplified configuration than FIG. 2. That is, in FIG. 3, unlike FIG. 2, the monitoring PD (300) is not attached to the stem base, but is arranged on a monitoring photodiode-embedded sub-mount (210). In other words, instead of the sub-mount (200) fixed between the laser diode chip (100) and the thermo-electric cooler (800), a monitoring PD-embedded sub-mount (210) with the monitoring PD (MPD) is applied. The monitoring PD embedded sub-mount (210) includes a laser diode chip (100) and an MPD (300) capable of receiving the beam from the laser diode chip (100) arranged around the laser diode chip (100), on the sub-mount. Therefore, the monitoring PD embedded sub-mount (210) can detect and control the optical output of the laser diode in the same way as in the conventional configuration and the configuration of FIG. 2a. Eliminating the need for an additional monitoring PD on the bottom surface of the stem base (400) can reduce assembly labor, processes, and package assembly costs while making packages more compact.

In other words, the configuration of FIG. 3 embodies a TO-CAN type package module without changing the laser beam path as in FIG. 2a, and simplifies the configuration of a TO-CAN type laser diode package module including a TEC to maintain a constant output and a constant wavelength variation width with temperature. In FIG. 3, pin 8 is connected to an MPD anode placed on a monitoring PD embedded sub-mount (210), and the connections of the remaining devices and pins are the same as in FIG. 2.

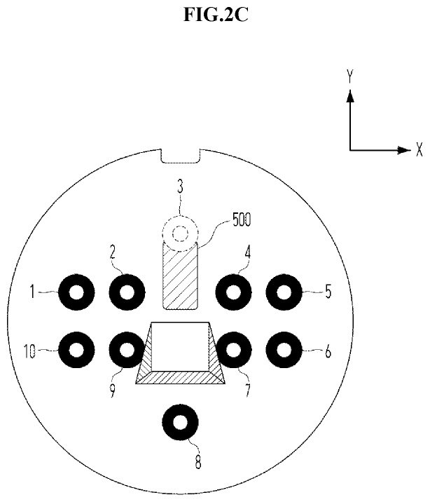

Meanwhile, as modified embodiments of the present invention, TO CAN type laser diode package modules are shown in FIG. 4 to FIG. 7, in which the heat block is omitted on the stem base (400), and the TEC (800) including the laser diode chip (100) is supported by bonding to lead pins.

That is, FIG. 4 shows a TEC (800) including a sub-mount (200) with a laser diode chip (100) fixed on it and a thermistor (900) (not shown) bonded to pins 2 and 9. The MPD (300) is disposed on the stem base (400) at a location capable of receiving beams from LD chip (100). The contact between the TEC (800) and the lead pins is electrically insulated, and the rear surface of the TEC (800) device may be originally made of an insulating material as a contact surface with the lead pins, or may be coated with an insulating material (e.g., a material such as ceramic). A thin plate of ceramic may be placed between the TEC (800) and the lead pins.

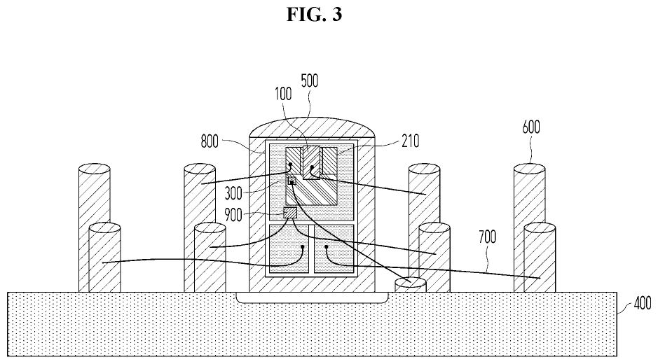

FIG. 5 shows a 90° shift in the placement of the TEC (800) device in FIG. 4 to support the TEC (800) device on pins 2 and 4. The MPD (300) is also repositioned to receive the beam from the LD chip (100).

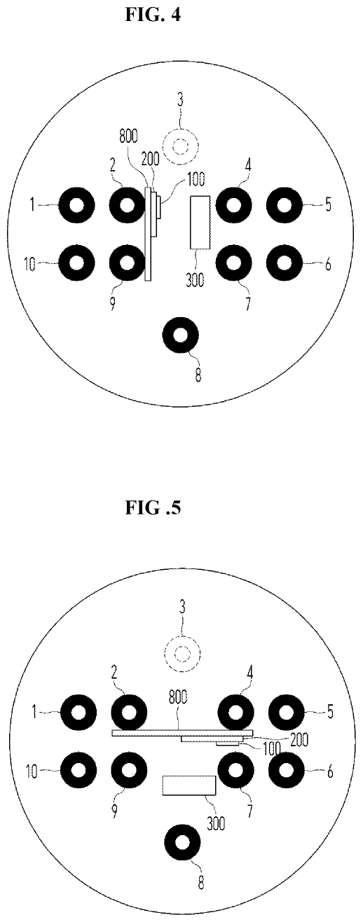

FIG. 6 shows a case in which the MPD (300) of FIG. 4 is placed on the monitoring PD embedded sub-mount (210) as shown in FIG. 3. That is, the TEC (800) device is fixed to pins 2 and 9, and the TEC (800) device includes a monitoring PD embedded sub-mount (210) to which the LD chip (100) and MPD (300) (not shown) are bonded, and a thermistor (800). The stem base (400) provides even more space.

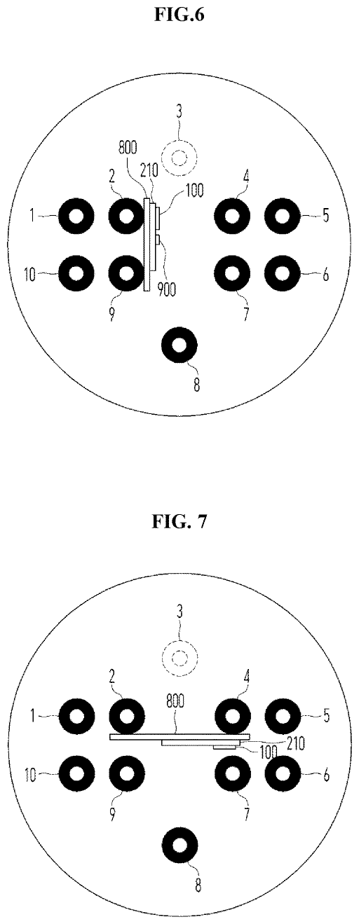

FIG. 7 shows a 90° reorientation of the TEC (800) device in FIG. 6, fixing the TEC (800) device to pins 2 and 4.

In this way, the optical properties of the laser diode chip (100) can be controlled by the TEC (800) device, allowing the omission of a heat block that provides support and heat dissipation, resulting in a more compact device and fewer assembly processes and labor.

Within the scope of the same technical concept, the above-described embodiments can be modified in various ways, and, for example, a position where the arrangement direction of each component is reversed along the X-axis and Y-axis in the stem base or a position where it is rotated 180 degrees corresponds to the scope of the present invention.

If not defined otherwise in the above description, all technical and scientific terms used in this specification have the same meaning as those commonly understood by a person skilled in the art to which the invention belongs. Furthermore, terms that are generally understood and defined in dictionaries are not interpreted ideally or excessively unless they are explicitly defined.

When a component is said to “include” or “have” another component in any part of the specification, it means that it can include other components unless there is a specific statement to the contrary. In addition, the singular form may include the plural form depending on the context.

In this context, “on˜ or above˜” means that the target part is located above or below something else, and it does not necessarily mean that it is located on the upper side based on the direction of gravity. Additionally, when a part such as an area or a plate is said to be “on or above” another part, it includes cases where there is another part in between them, not just when they are in direct contact with each other.

Further, when used in this specification, the terms “No. 1” and “No. 2” and the like are used to describe various components and are not limited to the components described by these terms. The terms are only used to distinguish one component from another.

In addition, when one component is referred to as “connected” or “linked” to another component in the present specification, it is to be understood that the component may be directly connected or linked to the other component, but may also be connected or linked through intermediary of another component, unless there is a specific contrary description.

Also, in the present specification, a singular representation in context may include a plural representation.

The rights of the present invention are not limited to the embodiments described above, and are defined by the claims, and it is apparent that a person skilled in the field of the invention can make various modifications and adaptations within the scope of the claims.

What is claimed is:

1. A TO CAN type laser diode package module including
a stem heat block including a stem base forming a bottom and a heat block protruding from the stem base;
a thermo-electric cooler (TEC) with a temperature control function, wherein the heat block has a surface including a vertical component, and the TEC is fixed to the surface including the vertical component of the heat block;
a sub-mount fixed on the thermo-electric cooler;
a laser diode chip and a thermistor fixed on the sub-mount;
a plurality of lead pins arranged at predetermined intervals on the stem base;
a monitoring photodiode (MPD) disposed on the stem base to monitor the beam emitted from the laser diode chip; and
wires connecting each of the devices to the lead pins,
wherein the TO CAN type laser diode package module is characterized in that emitted beams from the laser diode chip travel in the desired direction without changing its path.

2. A TO CAN type laser diode package module including:
a stem base forming a bottom;
a plurality of lead pins arranged at predetermined intervals on the stem base;
a thermo-electric cooler (TEC) with a temperature control function, supported and fixed by two of the lead pins;
a sub-mount fixed on the thermos-electric cooler;
a laser diode chip and a thermistor fixed on the sub-mount;
a monitoring photodiode (MPD) placed on the stem base to monitor beams emitted from the laser diode chip; and
wires connecting each of the devices to the lead pins,
wherein the TO CAN type laser diode package module is characterized in that emitted beams from the laser diode chip travel in the desired direction without changing its path.

3. A sub-mount module for a TO CAN type laser diode package module including:
a sub-mount;
a laser diode chip on the sub-mount;
a thermistor that monitors the temperature of the laser diode chip on the sub-mount; and
a monitoring photodiode (MPD) that monitors beams emitted from the laser diode chip on the sub-mount.

4. A TO CAN type laser diode package module including:
a stem heat block including a stem base forming a bottom and a heat block protruding from the stem base;
a thermo-electric cooler (TEC) with a temperature control function, wherein the heat block has a surface including a vertical component, and the TEC is fixed to the surface including the vertical component of the heat block;
the sub-mount module for the TO CAN type laser diode package module of claim 3 fixed to the thermo-electric cooler (TEC);
a plurality of lead pins arranged at predetermined intervals on the stem base;
and
wires connecting each of the devices to the lead pins,
wherein the TO CAN type laser diode package module is characterized in that emitted beams from the laser diode chip travel in the desired direction without changing its path.

5. A TO CAN type laser diode package module Including;
a stem base forming a bottom;
a plurality of lead pins arranged at predetermined intervals on the stem base;
a thermo-electric cooler (TEC) with a temperature control function, supported and fixed by two of the lead pins;
the sub-mount module for the TO CAN type laser diode package module of claim 3 fixed to the thermoelectric cooler (TEC);
and
wires connecting each of the devices to the lead pins,
wherein the TO CAN type laser diode package module is characterized in that emitted beams from the laser diode chip travel in the desired direction without changing its path.

6. A TO CAN type laser diode package module of claim 1, characterized in that some of the lead pins are arranged in two rows along the diameter of the stem base, with a diameter between them (in parallel to the X-axis direction), and others are arranged along the Y-axis direction from the center of the stem base.

7. A TO CAN type laser diode package module of claim 2, characterized in that some of the lead pins are arranged in two rows along the diameter of the stem base, with a diameter between them (in parallel to the X-axis direction), and others are arranged along the Y-axis direction from the center of the stem base.

8. A TO CAN type laser diode package module of claim 4, characterized in that some of the lead pins are arranged in two rows along the diameter of the stem base, with a diameter between them (in parallel to the X-axis direction), and others are arranged along the Y-axis direction from the center of the stem base.

9. A TO CAN type laser diode package module of claim 5, characterized in that some of the lead pins are arranged in two rows along the diameter of the stem base, with a diameter between them (in parallel to the X-axis direction), and others are arranged along the Y-axis direction from the center of the stem base.

10. A TO CAN type laser diode package module of claim 6, which characterizes in that the lead pins include eight, wherein pin 1 is an NC pin for signal input or inspection, pin 2 is connected to a cathode of the laser diode chip, pin 3 arranged behind the heat block, is connected to the monitoring photodiode anode, pin 4 is connected to an anode of the laser diode chip, pin 5 is the signal input pin, pin 6 is connected to the (−) terminal of a thermos-electric cooler, pins 7 and 9 are connected to a thermistor, pin 8 is connected to an MPD anode, and pin 10 is connected to the (+) terminal of a thermos-electric cooler.

11. A TO CAN type laser diode package module of claim 7, which characterizes in that the lead pins include eight, wherein pin 1 is an NC pin for signal input or inspection, pin 2 is connected to a cathode of the laser diode chip, pin 3 arranged behind the heat block, is connected to the monitoring photodiode anode, pin 4 is connected to an anode of the laser diode chip, pin 5 is the signal input pin, pin 6 is connected to the (−) terminal of a thermos-electric cooler, pins 7 and 9 are connected to a thermistor, pin 8 is connected to an MPD anode, and pin 10 is connected to the (+) terminal of a thermos-electric cooler.

12. A TO CAN type laser diode package module of claim 8, which characterizes in that the lead pins include eight, wherein pin 1 is an NC pin for signal input or inspection, pin 2 is connected to a cathode of the laser diode chip, pin 3 arranged behind the heat block, is connected to the monitoring photodiode anode, pin 4 is connected to an anode of the laser diode chip, pin 5 is the signal input pin, pin 6 is connected to the (−) terminal of a thermos-electric cooler, pins 7 and 9 are connected to a thermistor, pin 8 is connected to an MPD anode, and pin 10 is connected to the (+) terminal of a thermos-electric cooler.

13. A TO CAN type laser diode package module of claim 9, which characterizes in that the lead pins include eight, wherein pin 1 is an NC pin for signal input or inspection, pin 2 is connected to a cathode of the laser diode chip, pin 3 arranged behind the heat block, is connected to the monitoring photodiode anode, pin 4 is connected to an anode of the laser diode chip, pin 5 is the signal input pin, pin 6 is connected to the (−) terminal of a thermos-electric cooler, pins 7 and 9 are connected to a thermistor, pin 8 is connected to an MPD anode, and pin 10 is connected to the (+) terminal of a thermos-electric cooler.

14. A TO CAN type laser diode package module of claim 10, characterized in that pins 1, 2, 4, 5, 6, 7, 9, and 10 are arranged in two rows along the transverse diameter (X-axis direction) of the stem base, pin 3 is placed at a position shifted from the center of the stem base in the +Y axis direction, and pin 8 is placed at a position shifted from the center of the stem base in the −Y direction.

15. A TO CAN type laser diode package module of claim 11, characterized in that pins 1, 2, 4, 5, 6, 7, 9, and 10 are arranged in two rows along the transverse diameter (X-axis direction) of the stem base, pin 3 is placed at a position shifted from the center of the stem base in the +Y axis direction, and pin 8 is placed at a position shifted from the center of the stem base in the −Y direction.

16. A TO CAN type laser diode package module of claim 12, characterized in that pins 1, 2, 4, 5, 6, 7, 9, and 10 are arranged in two rows along the transverse diameter (X-axis direction) of the stem base, pin 3 is placed at a position shifted from the center of the stem base in the +Y axis direction, and pin 8 is placed at a position shifted from the center of the stem base in the −Y direction.

17. A TO CAN type laser diode package module of claim 13, characterized in that pins 1, 2, 4, 5, 6, 7, 9, and 10 are arranged in two rows along the transverse diameter (X-axis direction) of the stem base, pin 3 is placed at a position shifted from the center of the stem base in the +Y axis direction, and pin 8 is placed at a position shifted from the center of the stem base in the −Y direction.

18. A TO CAN type laser diode package module of claim 1, characterized in that a heat block is disposed in an eccentric part biased in the +Y direction from the center of a stem base.

19. A TO CAN type laser diode package module of claim 2, characterized by the presence of an insulator between the thermos-electric cooler and the lead pin supporting the thermos-electric cooler.

20. A TO CAN type laser diode package module of claim 5, characterized by the presence of an insulator between the thermos-electric cooler and the lead pin supporting the thermos-electric cooler.
